(19) United States
(12) Patent Application Publication
(10) Pub. No.: US 2007/0082479 A1
(43) Pub. Date: Apr. 12, 2007

(54) Chemical mechanical polishing techniques for integrated circuit fabrication

(75) Inventors: Deenesh Padhi, Santa Clara, CA (US); Girish Dixit, San Jose, CA (US)

Correspondence Address: PATENT COUNSEL;APPLIED MATERIALS, INC., Legal Affairs Department, P.O. Box 450A, Santa Clara, CA, 95052, US

(73) Assignee: Applied Materials, Inc.

(21) Appl. No.: 11/245,677

(22) Filed: Oct. 6, 2005

(51) Int. Cl. H01L 21/4763

(52) U.S. Cl. 438/629; 438/628; 438/626; 438/638

(57) ABSTRACT

The present invention provides methods for fabricating horizontal interconnect lines for use in semiconductor wafer fabrication. A dielectric layer is deposited on a dielectric stack having a planarized top surface. The dielectric layer is not planarized at this stage of the process. A pre-planarizing thickness profile of the non-planarized dielectric layer is determined and recorded. An interconnect line trench is then etched through the dielectric layer. A sandwich layer including a conductive Cu diffusion barrier layer and a Cu seed layer is deposited in the trench and on the dielectric layer. A Cu comprising metal is deposited in the sandwich lined trench. A Cu metal overburden is thereby deposited on the section of the sandwich layer that is positioned on the dielectric layer. A first CMP process is used to remove the Cu overburden and the Cu seed layer that is formed in the sandwich layer portion on the dielectric layer. A second CMP process is utilized wherein the pre-planarizing thickness profile is employed to remove the Cu barrier layer from the top surface of the dielectric layer, the second CMP process is then continued by planarizing the dielectric layer to form a substantially uniform flat surface having a substantially uniform thickness which is substantially equal to a predetermined design thickness. The second CMP process thereby results in fabricating a dielectric layer wherein substantially all interconnect lines have a substantially uniform thickness that is substantially equal to the design thickness for the dielectric layer.

### FIELD OF THE INVENTION

The present invention relates to chemical mechanical polishing and planarizing techniques for integrated circuit fabrication, particularly with regard to horizontal interconnects for integrated circuits.

### BACKGROUND OF THE INVENTION

A semiconductor device such as an integrated circuit (IC) generally has electronic circuit elements such as transistors, diodes and resistors fabricated integrally on a single body of semiconductor material. The various circuit elements are connected through conductive connectors to form a complete circuit which can contain millions of individual circuit elements. Interconnects provide the electrical connections between the various electronic elements of an IC and they form the connections between these elements and the device's external contact elements, such as pins, for connecting the IC to other circuits. Typically, interconnect lines form horizontal connections between electronic circuit elements while conductive vias form vertical connections between the electronic circuit elements, resulting in layered connections. A variety of techniques are employed to create interconnect lines and vias. One such technique involves a process generally referred to as dual damascene, which includes forming a trench and an underlying via hole. The trench and the via hole are then simultaneously filled with a conductor material, for example a metal, thus simultaneously forming an interconnect line and an underlying via.

Multiple integrated circuits are fabricated on a layered semiconductor wafer such that these integrated circuits are designed to each have identical composition, dimensions and performance. Metallization processes, such as forming the interconnect lines, occur on the back end of the line (BEOL) of the wafer. The finished wafer is cut into sections, each section forming a die that is processed to fabricate a microchip containing the complete IC.

Horizontal interconnect lines, also known as wires, are typically formed in a trench that is fabricated by etching a dielectric layer on the BEOL. A conductive material such as copper, aluminum or metal alloys is then deposited in the trench using such deposition techniques as electrochemical plating (ECP), electroless plating and physical vapor deposition (PVD). The deposition step usually results in overfilling the trench, thus forming an overburden of conductive material on the dielectric layer. In a next processing step, excess conductive material is removed to define the interconnect line and to remove the overburden. It is also necessary to process the wafer such that the dielectric layer is fabricated at a specified thickness and such that the exposed surface of the dielectric layer and the embedded interconnect line form a substantially flat surface, in order to fabricate interconnect lines having a substantially uniform thickness that meets the design requirements.

Advances in semiconductor materials and processing techniques have resulted in reducing the overall size of the IC elements while increasing their number on a single body of semiconductor material. Additional miniaturization is highly desirable for improved IC performance and cost reduction. Size reduction of IC elements includes reducing the diameter of interconnect lines to such an extend that the resistance and capacitance, typical of current and future interconnect lines, exceeds the gate delay at IC elements such as transistors. Die to die variations in resistance of the interconnect lines can result in differences in signal velocity and can thus cause undesirable die to die performance differences. It is therefore known to persons of ordinary skill in the art that it is highly important to control IC interconnect line resistance in order to achieve die to die performance uniformity and reproducibility.

Chemical mechanical polishing (CMP) is a widely used technique for removing excess conductive material. Additionally, this technique can also be utilized to planarize the exposed surface of the wafer to optimize the topography of the exposed wafer surface by forming a uniform flat surface. The CMP planarization process employs an abrasive slurry that is carried between the wafer surface and a polishing pad while the wafer surface is moved against the pad in a highly controlled manner, controlling for example the pressure that is exerted by the pad on the wafer surface, the type and velocity of wafer motion relative to the pad and the processing temperature. The abrasive slurry contains ingredients that chemically affect the planarization for example by dissolving wafer surface materials in a controlled manner.

An example of a conventional CMP apparatus suitable for CMP planarizing is schematically illustrated in FIG. 1 showing a CMP apparatus 100. The apparatus includes one or more polishing stations 110 having a rotatable platen 112 upon which is placed a polishing pad 114. During polishing, the platen is rotated at a controlled speed. A pad conditioner 116 is usually employed to maintain the abrasive condition of the pad. A combined slurry/rinse application mechanism 118 can be used to deposit an abrasive slurry, typically including a reactive agent, on the top surface of polishing pad 114. Slurry/rinse application mechanism 118 usually includes one or more spray nozzles (not shown) for rinsing the polishing pad at the end of the polishing cycle.

CMP apparatus 100 further includes one or more carrier head systems 120 supported by a post 121. Each carrier head system 120 is provided with a polishing or carrier head 122 which holds a substrate, such as a semiconductor wafer 124. Carrier head 122 rotates about its axis using a shaft 126, and typically oscillates laterally in a radial slot 128 in a support member 130.

During polishing, carrier head 122 lowers substrate 124 and places the substrate in contact with rotating polishing pad 114. The carrier head rotates the substrate and holds it in position against the polishing pad thereby distributing a force against the surface of the substrate. The carrier head can also transfer torque from the drive shaft to the substrate. A more detailed illustration and description of a CMP apparatus suitable for planarizing semiconductor wafers can for example be found in U.S. Pat. No. 6,439,964 to Prahbu et al., 2002 (the '964 patent) and U.S. Pat. No. 6,422,927 to Zuniga, 2002 (the '927 patent). Generally, a CMP apparatus is controlled by a computer program that controls polishing variables such as platen rotation rates and pressure for example to control different material removal rates at different zones of the wafer surface. It is common practice to use CMP equipment that uses a multiple platen system, typically two or three platen, to more precisely control CMP material removal rates and to obtain different removal rates at different wafer zones. It is also known to use CMP by using an abrasive belt (not shown) instead of an abrasive pad.

Techniques utilized for CMP planarizing of dielectric layers attempt to remove dielectric material from the top surface of a dielectric layer in a substantially uniform manner in order to obtain a dielectric layer having a uniform flat surface and a specific thickness. It is highly desirable to planarize the dielectric layer such that the layer has a substantially uniform thickness meeting the design thickness tolerances. Significant thickness variations in a dielectric layer that is used for fabricating one or more interconnect lines, i.e. a metallizing layer, can result in significant thickness variations in the interconnect lines and can thus affect the performance of the microchip. Also, it is highly desirable to fabricate multiple wafers for the same IC design such that there are no significant wafer to wafer thickness differences for the corresponding dielectric metal layers, in order to fabricate IC microchips having reproducible and substantially uniform thickness of interconnect lines, even when fabricated from different wafers.

Employing conventional CMP planarizing techniques, it is well known that it is difficult to fabricate dielectric layers having a high degree of surface flatness and having a uniform thickness within fairly narrow thickness tolerances. For example, commonly known CMP planarizing problems can include radial differences such as a raised thickness near the center of the wafer, as well as concentric bands on the planarized surface that are formed due to greater or lesser amounts of material removal. Planarizing difficulties also arise from non-uniform material removal rates due to the presence of for example metal overburden resulting from metal deposition or from layers such as barrier/seed layers which have different removal rates than the dielectric layer material upon which the overburden or the barrier/seed layer has been deposited. Non-uniform CMP material removal rates can also be caused by different slurry reaction rates with respect to different materials being present in the surface.

Generally, CMP planarizing difficulties concerning radial effects such as increased center thickness are greatly reduced or overcome through the use of CMP planarizing techniques wherein the material removal rate is adjusted radially, for example employing a greater polishing pad pressure or greater polishing pad rotating speed on wafer areas requiring a higher removal rate. However it is generally much more difficult to successfully planarize dielectric layers having metal deposition since this type of deposition typically results in flatness non-uniformity that is not radial. These problems are aggravated when a high degree of wafer to wafer interconnect line thickness uniformity is required. Planarizing difficulties that result in non uniform flatness and/or thickness of the dielectric metal layer are known to cause performance problems and to cause significant manufacturing inefficiencies. It is therefore desirable to develop CMP planarizing techniques for semiconductor wafers that provide improved dielectric layer surface flatness and thickness uniformity in order to improve the thickness uniformity of horizontal interconnect lines that are formed in these dielectric layers and to thereby improve the uniformity of interconnect line resistance.

### SUMMARY OF THE INVENTION

In one embodiment of the invention a dielectric stack is formed such that the dielectric stack has a planarized top surface. A dielectric layer is deposited on this dielectric stack wherein the dielectric layer has a top surface that is non-planarized, and wherein the dielectric layer thickness at its thinnest section at least equals the design thickness for this layer. The pre-planarizing thickness profile of the non-planarized layer is then determined and recorded. A trench is subsequently etched through the dielectric layer, preferably stopping the trench etching on an etch stop layer. Thereafter, an electrically conductive substantially conformal Cu diffusion barrier layer is conformally deposited in the trench and on the top surface of the dielectric layer. A conformal Cu seed layer is deposited on the Cu barrier layer thereby forming a barrier/seed sandwich layer, resulting in a sandwich layer lined trench. Cu is deposited in the lined trench. This Cu deposition process also forms a Cu overburden on the portion of the sandwich layer that is deposited on the non-planarized dielectric layer. A first CMP process, that is selective to the Cu barrier layer and to the dielectric layer is used to remove Cu overburden and to remove Cu seed layer from the portion of the sandwich layer that is deposited on the dielectric layer. A second CMP process, that utilized the pre-planarizing thickness profile, is executed to remove the portion of the Cu diffusion barrier layer that is deposited. This is followed by planarizing the dielectric layer to define the interconnect line and fabricate the dielectric layer thickness to the design thickness for this layer. This process results in interconnect lines having a substantially uniform thickness that meets the design thickness specification.

In another embodiment of the present invention a first dielectric layer is deposited on a dielectric stack, whereafter the top surface of the first dielectric layer is planarized. Subsequently, a second dielectric layer is deposited on the first dielectric layer. The top surface of the second dielectric layer is not planarized at this stage of the process. The thickness of the second dielectric layer at its thinnest point is at least equal to the design thickness for this layer. The pre-planarizing thickness profile of the second dielectric layer is then determined and saved for later use. A trench and an underlying via hole are subsequently formed in the second dielectric layer such that the trench extends through the second dielectric layer while the via hole extends at least through the first dielectric layer. The bottom of the trench is open to the via hole. Thereafter an electrically conductive conformal Cu diffusion barrier layer is deposited in the via hole and in the trench as well as on the top surface of the dielectric layer. A conformal Cu seed layer is deposited on the Cu barrier layer thereby forming a barrier/seed sandwich layer, resulting in a sandwich layer lined via hole and sandwich layer lined trench. Cu is deposited in the lined via hole and in the lined trench. This deposition process also forms a Cu overburden on the portion of the sandwich layer that is deposited on the non-planarized dielectric layer. A first CMP process, that is selective to the Cu barrier layer and to the dielectric layer is used to remove Cu overburden and to remove Cu seed layer from the portion of the sandwich layer that is deposited on the dielectric layer. A second CMP process, that utilized the pre-planarizing thickness profile, is executed to remove the portion of the Cu diffusion barrier layer that is deposited on the dielectric layer and to then planarize the dielectric layer to define the interconnect line and fabricate the second dielectric layer thickness to the design thickness for this layer. This process results in interconnect lines having a substantially uniform thickness that meets the design thickness specification.

### BRIEF DESCRIPTION OF THE DRAWINGS

FIG. 1 is a schematic illustration of a conventional CMP apparatus.

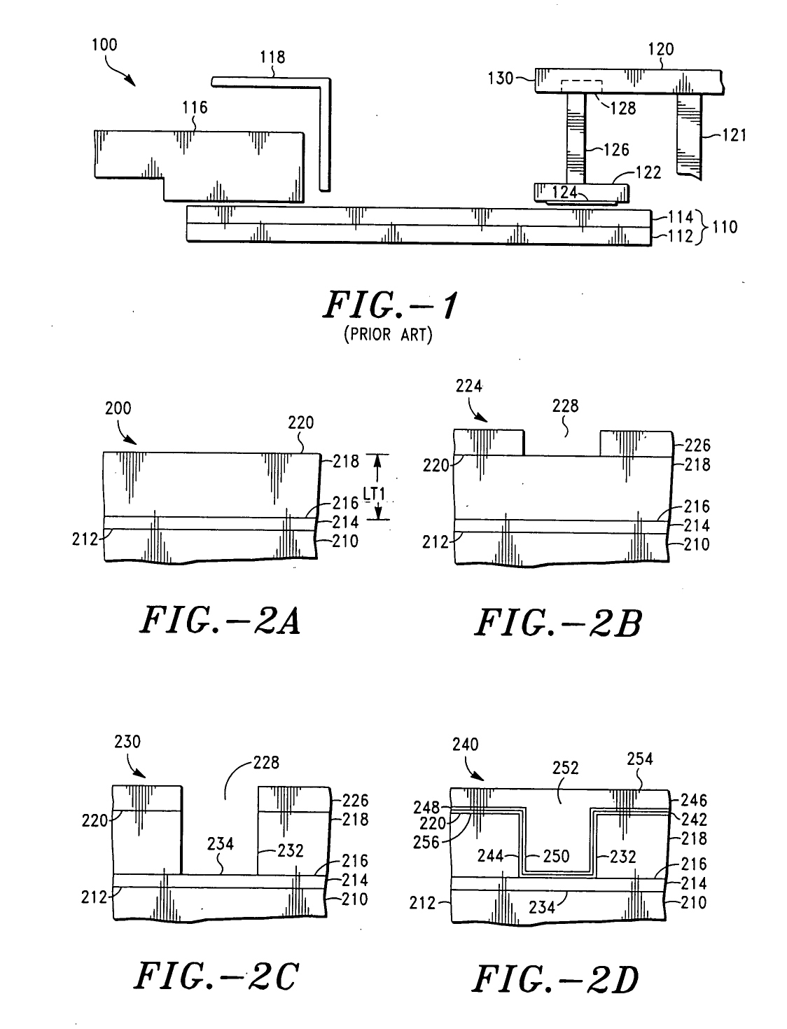

FIGS. 2A-2F are schematic cross-sectional views illustrating an embodiment of IC structures of the present invention at sequential stages.

FIGS. 3A-3D are schematic cross-sectional views illustrating an embodiment of IC structures of the present invention at sequential stages.

FIGS. 4A-4H are schematic cross-sectional views illustrating an embodiment of IC structures of the present invention at sequential stages.

### DETAILED DESCRIPTION OF THE INVENTION

While describing the invention and its embodiments, certain terminology will be utilized for the sake of clarity. It is intended that such terminology includes the recited embodiments as well as all equivalents.

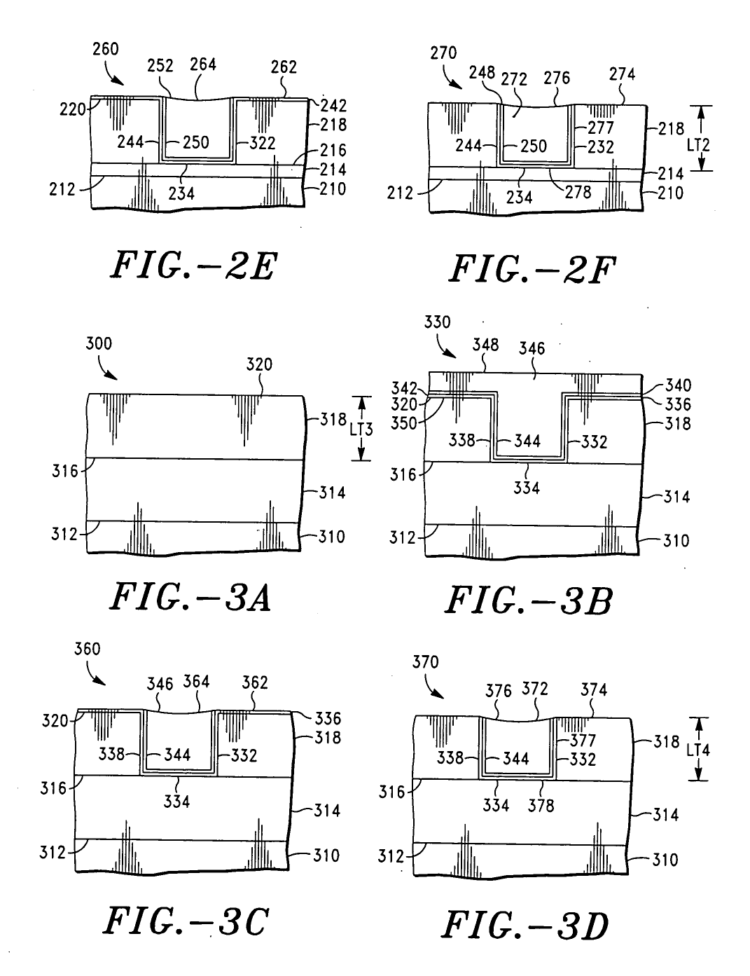

One embodiment of the present invention, schematically illustrated in FIGS. 2A-2F, shows a novel processing sequence for forming IC structures including a horizontal interconnect line. The expression “integrated circuit structure” as defined herein, means completely formed integrated circuits and partially formed integrated circuits. The expression “horizontal” as defined herein, means substantially parallel to the wafer surface upon which the horizontal line is fabricated.

FIG. 2A shows an IC structure 200 having a semiconductor substrate 210 including a substrate top surface 212. The term “semiconductor substrate” as defined herein, means structures or devices comprising typical IC elements, components and semiconductor materials. The expression “semiconductor structure” as defined herein, means a structure comprising a semiconductor material, and/or a semiconductor element such as a transistor, and/or a semiconductor substrate. Substrate top surface 212 is prepared using conventional planarizing techniques such as CMP, to obtain a uniform planar surface. An etch stop layer 214 is then deposited on substrate top surface 212. Top surface 216 of etch stop layer 214 is fabricated using conventional CMP planarizing techniques to obtain a uniform planar top surface. Subsequently, using conventional deposition techniques, a dielectric layer 218 is deposited on planarized surface 216 of etch stop layer 214. Typically, the thickness of layer 218 is not uniform when commonly practiced dielectric layer deposition techniques are employed. However, at its thinnest point or section, the thickness LT1 (FIG. 2A) of layer 218 should equal or exceed design thickness DT1 for layer 218. Utilizing a novel technique of the present invention, top surface 220 of layer 218 is not planarized at this stage of the fabricating process.

With reference to FIG. 2A, conventional metrology techniques are employed to determine the thickness profile of non-planarized dielectric layer 218. Examples of metrology systems suitable for measuring a thickness profile of the present invention include system P2 available from KLA-Tencor of San Jose, Calif. The term “thickness profile” as defined herein means a two-dimensional representation of an edge-to-edge vertical cross section of the layer through the center of the wafer, indicating the edge-to-edge thickness of the layer at each point or section of the layer. This representation can be provided in a graphical form such as a chart, a numerical form, or an electronic form. Preferably, a digital database is created wherein the thickness profile is expressed in coordinates using conventional computer controlled methods, see for example the '964 patent and U.S. Pat. No. 6,540,591 to Pasadyn et al. (the '591 patent). The thickness profile thus obtained is designated herein as the pre-planarizing thickness profile (PPTP). The PPTP of layer 218 is saved for later use in the IC fabricating sequence, as will be described in more detail in connection with FIG. 2F.

With reference to FIG. 2B, an IC structure 224 is fabricated by depositing a conventional photoresist layer 226 on non-planarized surface 220 of dielectric layer 218. Preferably, resist layer 226 is a conformal layer. Resist layer 226 is then developed to form a conventional trench etching mask 228.

Then, as illustrated in FIG. 2C, an IC structure 230 is formed by etching a trench 232 through non-planarized dielectric layer 218, such that etch stop layer 214 stops the trench etching process. Bottom 234 of trench 232 is thus exposed to etch stop layer 214. This etch process requires that dielectric layer 218 and etch stop layer 214 have dissimilar etching characteristics. The expression “dissimilar etching characteristics” of two materials or layers as defined herein, means etching properties of these materials or layers such that one of the materials or layers has a higher etch rate than the other material or layer in a specific etch chemistry. Suitable materials and etch chemistries for etching trench 232 include etch techniques that are selective to etch stop layer 214. The etch process for etching trench 232 includes anisotropic etch techniques. Techniques for fabricating an interconnect trench in a dielectric layer, such as trench 232 in layer 218 are known to a person of ordinary skill in the art.

The processing sequence is continued by fabricating an IC structure 240, depicted in FIG. 2D. Resist layer 226 is removed, after which an electrically conductive conventional conformal Cu diffusion barrier layer 242 is deposited on bottom 234 of trench 232 and on sidewalls 244 of the trench. Barrier layer 242 is also deposited on non-planarized top surface 220 of dielectric layer 218. A conventional conformal Cu seed layer 246 is deposited on barrier layer 242. Barrier layer 242 and Cu seed layer 246 form a barrier/seed sandwich layer 248, see FIG. 2D. Typical Cu diffusion barrier materials for use in layer 242 include, but are not limited to, conductors for example refractory metals such as Ta, Ti, TiW and compounds of refractory metals such as TiN, TiC, TaN and TaC, as well as combinations of these materials such as TaN/Ta and Ti/TaN/Ta. Conventional materials for Cu seed layer 246 include Cu and Cu alloys typically having a low percentage of one or more other metals. Suitable techniques for depositing barrier/seed sandwich layer 248 are known to those of ordinary skill in the art. Deposition of barrier/seed sandwich layer 248 results in a lined trench 250.

As shown in FIG. 2D, Cu is deposited in lined trench 250 forming a Cu trench deposit 252. This also forms a Cu overburden 254 on portion 256 of sandwich layer 248 that is deposited on dielectric layer 218. Cu deposition techniques for use in embodiments of the present invention include conventional electrochemical plating (ECP) Cu deposition methods. Barrier/seed sandwich layer 248 is utilized as the cathode for the ECP deposition technique.

IC structure 240 (FIG. 2D) is then subjected to a two stage CMP technique. The first stage of the CMP technique includes a first CMP process for removal of Cu overburden 254, and Cu seed layer 246 of portion 256 of barrier/seed sandwich layer 248 that is deposited on top surface 220 of dielectric layer 218. This first CMP stage utilizes a first CMP process that is selective to barrier layer 242 and dielectric layer 218. The required CMP selectivity can for example be obtained through the use of a conventional CMP slurry that is selective to the materials of barrier layer 242 and dielectric layer 218. The first stage CMP technique results in an IC structure 260 as depicted in FIG. 2E. IC structure 260 includes a top surface 262 comprising barrier layer 242 and top surface 264 of Cu trench deposit 252. It is noted that top surface 262 of IC structure 260 does not comprise a uniform planar surface since top surface 262 has a topography that is similar to the topography of top surface 220 of non-planarized dielectric layer 218. Typically, Cu top surface 264 can be slightly dished as a result of this CMP technique.

The second stage of the CMP technique includes a second CMP process wherein the PPTP that is obtained for non-planarized dielectric layer 218, as described in connection with IC structure 200 (FIG. 2A), is utilized in a conventional CMP apparatus. CMP techniques of the present invention are then employed, using the PPTP in connection with structure 260 (FIG. 2E) in order to remove barrier layer 242 from top surface 220 of dielectric layer 218 and to then planarize layer 218 such that layer 218 has a substantially uniform flat top surface and a substantially uniform thickness LT2 that is substantially equal to design thickness DT1, thereby forming IC structure 270 shown in FIG. 2F. As shown in FIG. 2F, the second stage of the CMP technique results in defining a Cu interconnect line 272 that is formed in lined trench 250. Interconnect line 272 includes sandwich layer coated side walls 277 and sandwich layer coated bottom 278. Structure 270 includes a substantially uniform flat top surface 274, including top surface 276 of Cu interconnect line 272. Typically, Cu top surface 276 can be slightly dished. Interconnect line 272 includes a substantially uniform thickness IT1 that is substantially equal to design thickness DT1 because the interconnect line is fabricated in planarized dielectric layer 218 to a thickness LT2=DT1. Suitable computer control methods for planarizing IC structure 260 (FIG. 2E) to a substantially uniform flat surface include the conventional methods that are described in the '964 and '591 patents.

Typical CMP conditions for executing the two stage CMP techniques of the present invention include the use of a 3 platen process wherein the slurry composition and the polishing conditions are chosen to obtain a uniform thickness profile and a substantially flat surface, as well as a controlled thickness that is substantially equal to the design thickness.

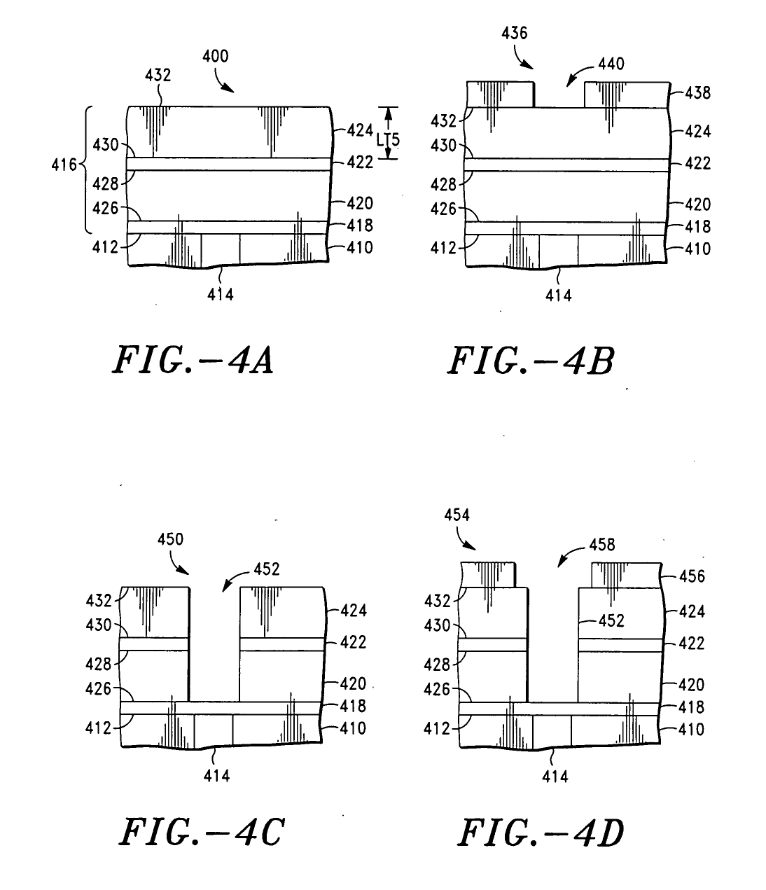

In a further embodiment of the present invention, novel techniques are employed for fabricating interconnect lines in a dielectric layer, such as a metallizing layer, that is deposited on a dielectric layer that is formed on a semiconductor substrate as illustrated in FIGS. 3A-3D. IC structure 300, depicted in FIG. 3A, includes a semiconductor substrate 310 having a top surface 312 that has been planarized to obtain a uniform flat surface. A conventional first dielectric layer 314 including a top surface 316 is deposited on substrate 310. Top surface 316 is prepared by employing conventional CMP planarizing techniques to fabricate a uniform flat top surface. Thereafter, a conventional second dielectric layer 318 is deposited on first dielectric layer 314, such that layers 314 and 318 have dissimilar etching characteristics. Top surface 320 of layer 318 is not planarized at this stage of the process, similar to top surface 220 of layer 218 shown in FIG. 2A. Returning to FIG. 3A, it is noted that the non-planarized thickness of layer 318 is generally not uniform when commonly practiced dielectric layer deposition techniques are used. However, at its thinnest point or section, thickness LT3 of layer 318 should equal or exceed design thickness DT2 for layer 318. Utilizing methods and techniques described in connection with IC structure 200 shown in FIG. 2A, the PPTP of layer 318 (FIG. 3A) is measured and saved for later use in the fabrication sequence of the present invention as will be described in connection with IC structure 370 shown in FIG. 3D.

With reference to FIG. 3B an IC structure 330 is fabricated. An interconnect line trench 332 is etched in second dielectric layer 318, utilizing techniques and materials similar to those described in connection with FIGS. 2A-2C and employing an etch chemistry that is selective to first dielectric layer 314. In this etching process first dielectric layer 314 (FIG. 3B) is an etch stop for etching trench 332, wherein bottom 334 of trench 332 exposes top surface 316 of dielectric layer 314. Subsequently, using techniques and materials similar to those illustrated and described in connection with FIG. 2D, a conventional conformal conductive Cu barrier layer 336 is deposited on bottom 234 and side walls 338 of trench 332, as well as on non-planarized top surface 320 of layer 318, see FIG. 3B. Subsequently, the techniques described in connection with FIG. 2D are utilized to deposit a conformal Cu seed layer 340 on barrier layer 336, thereby forming a barrier/seed sandwich layer 342 as shown in FIG. 3B. Deposition of barrier/seed sandwich layer 342 results in a lined trench 344. Conventional ECP methods are employed to deposit Cu in lined trench 344 to form a Cu trench deposit 346. This also forms a Cu overburden 348 on portion 350 of sandwich layer 342 that is deposited on dielectric layer 318.

IC structure 330 (FIG. 3B) is subjected to a two stage CMP technique similar to the techniques described and illustrated in connection with FIGS. 2D-2F. The first stage of these techniques includes a first CMP process for removal of Cu overburden 348 and Cu seed layer 340 of portion 350 of barrier/seed sandwich layer 342 that is deposited on top surface 320 of dielectric layer 318, thereby forming IC structure 360 illustrated in FIG. 3C. By analogy with IC structure 260, shown in FIG. 2E, it is noted that top surface 362 of IC structure 360 (FIG. 3C) does not comprise a uniform planar surface since top surface 362 has a topography that is substantially similar to non-planarized top surface 320 of dielectric layer 318. Typically, top surface 364 of Cu trench deposit 346 can be slightly dished as a result of this CMP technique.

An IC structure 370 is fabricated, as depicted in FIG. 3D, by employing a second CMP stage employing a second CMP process illustrated and described in connection with structure 270 depicted in FIG. 2F, and using the PPTP that is obtained for non-planarized layer 320 of IC structure 300, depicted in FIG. 3A. Returning to FIG. 3D, the second stage of the CMP technique results in defining a Cu interconnect line 372 that is formed in lined trench 344 of dielectric layer 318 which is planarized at the design thickness DT2. Interconnect line 372 includes sandwich layer coated side walls 377 and sandwich layer coated bottom 378. IC structure 370 includes a substantially uniform flat top surface 374 of second dielectric layer 318 including a top surface 376 of Cu interconnect 372 that can be slightly dished. Interconnect line 372 includes a substantially uniform thickness IT2 that is substantially equal to design thickness DT2 because the interconnect line is fabricated in planarized layer 318 to a thickness LT4=DT2.

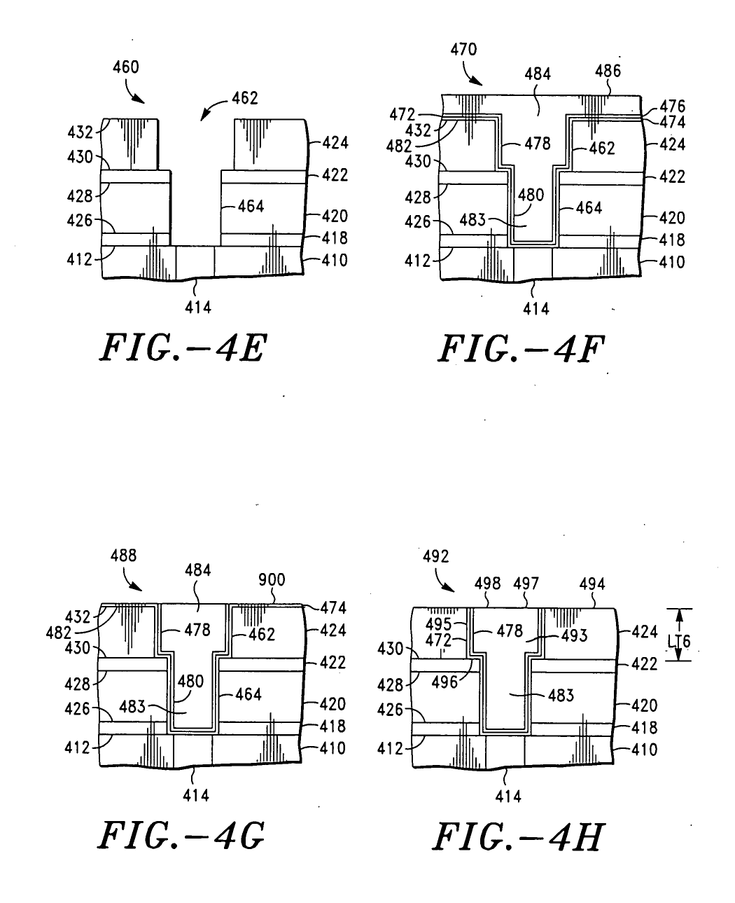

In an additional embodiment of the present invention, novel techniques are utilized to form dual damascene structures as described and illustrated in connection with FIGS. 4A-4H. With reference to FIG. 4A, an IC structure 400 is fabricated. IC structure 400 includes a semiconductor substrate 410 having a planarized top surface 412 and an electrically conductive element 414 that provides an electrically conductive contact with IC elements (not shown) of substrate 410. A conventional dielectric stack 416 is deposited on layer 410 by sequential deposition of a first etch stop layer 418, a first dielectric layer 420, a second etch stop layer 422 and a second dielectric layer 424. First etch stop layer 418 and second etch stop layer 422 have dissimilar etching characteristics. First dielectric layer 420 can comprise dielectric materials that are different from second dielectric layer 424, or that are substantially the same as the materials of second dielectric layer 424. Top surfaces 426, 428 and 430 of layers 418, 420 and 422 respectively are planarized prior to the deposition of the layer that is deposited on each of these top surfaces.

Typically, the thickness LT5 of layer 424, shown in FIG. 4A, is not uniform when commonly practiced dielectric layer deposition techniques are employed. However, at its thinnest point or section, the thickness of layer 424 should equal or exceed design thickness DT3 for layer 424. Employing novel techniques of the present invention, top surface 432 of second dielectric layer 424 is not planarized at this stage of the process, similar to top surface 220 of dielectric layer 218, depicted in FIG. 2A. Returning to FIG. 4A, the PPTP of non-planarized dielectric layer 424 (FIG. 4A) is then determined and saved for later use, employing techniques similar to those utilized in connection with non-planarized layer 218 of IC structure 200 shown in FIG. 2A.

The processing sequence is continued as illustrated in IC structure 436 shown in FIG. 4B. A conventional first photoresist layer 438 is deposited on non-planarized top surface 432 of second dielectric layer 424. The resist is then developed to form a conventional via etch mask 440, overlaying contact element 414 of substrate 410. Thereafter, IC structure 450 is formed, see FIG. 4C. IC structure 450 includes a via hole 452 that is prepared by etching the via pattern of via etch mask 440 successively through layers 424, 422 and 420. First etch stop layer 418 is the etch stop for etching via hole 452. Upon completion of the via etch procedure, first resist layer 438 (FIG. 4B) is removed from dielectric layer 422 as shown in FIG. 4C. Etch techniques for forming a via hole such as via hole 452 in an IC structure such as IC structure 450 are known to a person of ordinary skill in the art.

As illustrated in FIG. 4D, an IC structure 454 is fabricated by depositing a conventional second photoresist layer 456 on layer 424, and developing second photoresist layer 456 to from a conventional etch trench mask 458 in second resist layer 456. Trench etch mask 458 overlays via hole 452, see FIG. 4D. With reference to IC structure 460, shown in FIG. 4E, a trench 462 is formed by etching the trench etch pattern of trench etch mask 458 through second dielectric layer 424, using second etch layer 422 to stop the trench etch process. Then, using etching conditions that are selective to second etch stop layer 424 but not to first etch stop layer 418, the via pattern is etched through first etch stop layer 418. Second photoresist layer 456 is then removed, as shown in FIG. 4E. The trench etching process results in forming a trench 462, such as an interconnect line trench, extending through second dielectric layer 424, and a via hole 464 extending through first etch stop layer 418, first dielectric layer 420 and second etch stop layer 422. Etch techniques for forming a trench such as trench 462 and a via hole such as via hole 464 in IC structure 460 are known to a person of ordinary skill in the art.

Using methods and materials such as those employed in forming IC structures such as IC structures 240 (FIG. 2D) and 330 (FIG. 3B), IC structure 470 is formed, see FIG. 4F, by depositing a conventional conformal barrier/seed sandwich layer 472 inside via hole 464 and trench 462 as well as on non-planarized top surface 432 of second dielectric layer 424. Barrier/seed layer 472 comprises a conventional conductive Cu diffusion barrier layer 474 and a conventional Cu seed layer 476. The barrier/seed deposition process results in forming a lined trench 478 (FIG. 4F) and a lined via hole 480. Portion 482 of barrier/seed layer 472 extends on non-planarized top surface 432 of second dielectric layer 424.

The fabricating sequence is continued by simultaneous deposition of Cu in lined via hole 480 and in lined trench 478, employing conventional Cu deposition techniques and materials such as described in connection with IC structure 240 shown in FIG. 2D, as well as techniques for dual damascene fabrication methods that are known to a person of ordinary skill in the art. Returning to FIG. 4F, depositing Cu results in forming a Cu via 483 inside lined via hole 480 as well as a Cu deposit 484 inside lined trench 478. This process also results in forming a Cu overburden 486 on portion 482 of barrier/seed sandwich 472 extending on second dielectric layer 424, see FIG. 4F.

IC structure 470 (FIG. 4F) is subjected to a two stage CMP technique similar to the techniques described and illustrated in connection with FIGS. 2D-2F. The first stage of these techniques includes a first CMP process for removal of Cu overburden 486 and Cu seed layer 476 of portion 482 of barrier/seed sandwich layer 472 that is deposited on top surface 432 of dielectric layer 424, thereby forming IC structure 488 illustrated in FIG. 4G. By analogy with IC structure 260, shown in FIG. 2E, it is noted that top surface 490 of IC structure 488 (FIG. 4G) does not comprise a uniform planar surface since top surface 490 has a topography that is similar to non-planarized top surface 432 of dielectric layer 424.

An IC structure 492 is fabricated, as depicted in FIG. 4H, by employing a second CMP stage employing a second CMP process illustrated and described in connection with FIGS. 2F and 3D, and using the PPTP that is obtained for non-planarized IC structure 400, depicted in FIG. 4A. Returning to FIG. 4H, the second stage of the CMP technique results in defining a Cu interconnect line 493 that is formed in lined trench 478. Interconnect line 493 is fabricated in second dielectric layer 424 which is planarized at the design thickness DT3. Interconnect line 493 comprises sandwich layer coated sidewalls 495 and sandwich layer coated bottom 496. IC structure 492 includes a substantially uniform flat top surface 494 of second dielectric layer 428 including a top surface 497 of Cu interconnect 493 that can be slightly dished. Interconnect line 493 includes a thickness IT3 that is substantially equal to design thickness DT3 because the interconnect line is fabricated in planarized second dielectric layer 424 to a thickness LT6=DT3.

With reference to FIG. 4H, via 482 and interconnect line 493 comprise a dual damascene structure 498 that is formed according the novel methods of the present invention. This dual damascene structure is encased in barrier/seed sandwich layer 472 except for surface 497 of the interconnect line.

It will be understood that FIGS. 4A-4H and IC structures 400 - 492 are merely illustrative of the novel techniques of the present invention in connection with dual damascene technology. It is known to a person of ordinary skill in the art that there are many conventional methods for fabricating an IC structure comprising an interconnect trench and an underlying via hole formed in a dielectric stack wherein the trench and via hole are adapted for simultaneous filling with a conductive material, for example a metal such as copper, to form an interconnect line having an underlying via that is fabricated at the bottom surface of the interconnect line.

Techniques of the present invention, as exemplified in IC structures illustrated in FIGS. 2A-2F, 3A-3D and 4A-4H, result in a dielectric layer wherein the horizontal interconnect lines that are therein fabricated have a substantially uniform thickness that is substantially equal to the design thickness of the dielectric layer. This can be duplicated in multiple wafers providing the thickness of the non-planarized dielectric layer is at least equal to the design thickness for this layer. Techniques of the present invention can thus be utilized for fabricating wafers wherein a given interconnect line has substantially the same resistance in each of the integrated circuits that are formed in the wafer. These techniques are also suitable for fabricating multiple wafers wherein a given interconnect line has substantially the same resistance in each of the integrated circuits that are formed in each of the wafers, by for example using multiple wafers each having a metal line dielectric layer that utilizes the techniques of the present invention at the same design thickness, preferably when the interconnect lines are fabricated in metal line dielectric layers that comprise substantially the same materials.

Suitable dielectric materials for dielectric layers of the present invention include silicon oxide. The expression “silicon oxide” as defined herein, includes SiO₂ and related non-stoichiometric materials SiOX. Materials that are also suitable for use in dielectric layers of the present invention include, but are not limited to, related silica glasses such as USG (undoped silica glass), FSG (fluorinated silica glass), borophosphosilicaste glass (BPSG) and C-doped silicon oxide including oxidized organo silane materials having a carbon content of at least 1% by atomic weight such as BLACK DIAMOND™ technology available from Applied Materials, Inc. located in Santa Clara, Calif. Suitable dielectric materials further include, but are not limited to, amorphous fluorinated carbon based materials, spin-on dielectric polymers such as fluorinated and non-fluorinated poly(arylene) ethers (commercially known as FLARE 1.0 and 2.0, which are available from Allied Signal Company), poly(arylene) ethers (commercially known as PAE 2-3, available from Schumacher Company), divinyl siloxane benzocyclobutane (DVS-BCB) or similar products and aero-gel.

Suitable materials for etch stop layers of the present invention include, but are not limited to SiN, SiC and oxynitride.

While interconnect line and dual damascene metal depositions of the present invention are exemplified by conventional ECP Cu, it is noted that conventional ECP of Cu comprising metals such as Cu and conventional Cu alloys, as well as conventional electroless methods for depositing Cu comprising metals are suitable for use with the technologies of the present invention.

It will be understood that it is necessary to clean or prepare the surface of an IC structure prior to the deposition of any layer in any subsequent fabrication step, using surface preparation methods and materials that are known to those of ordinary skill in the art.

The terms “substantial” and “substantially” as used herein mean at least 90% of the relevant 100%.

The invention has been described in terms of exemplary embodiments of the invention. One skilled in the art will recognize that it would be possible to construct the elements of the present invention from a variety of means and to modify the placement of components in variety of ways. While the embodiments of the invention have been described in detail and shown in the accompanying drawings, it will be evident that various further modifications are possible without departing from the scope of the invention as set forth in the following claims.

We claim:

1. A method of forming an IC structure, the method comprising:
a) forming a dielectric stack including (1) a planarized top surface and (2) a semiconductor substrate;
b) depositing a dielectric layer on the planarized surface of the dielectric stack, wherein the dielectric layer includes a non-planarized top surface;
c) determining a pre-planarized thickness profile of the dielectric layer;
d) etching a trench through the dielectric layer;
e) conformally depositing an electrically conductive Cu diffusion barrier layer inside the trench and on the non-planarized surface of the dielectric layer;
f) conformally depositing a Cu seed layer on the Cu diffusion barrier layer, thereby fabricating a barrier/seed sandwich layer, wherein (1) a first portion of the sandwich layer is fabricated inside the trench thereby forming a lined trench and (2) a second portion of the sandwich layer covers the non-planarized surface of the dielectric layer;
g) depositing a Cu comprising metal inside the lined trench, thereby additionally forming a Cu comprising metal overburden on the second portion of the sandwich layer;
h) employing a first CMP process for removing (1) the Cu comprising metal overburden, (2) the Cu seed layer of the second portion of the sandwich layer and (3) wherein the first CMP process does not utilize a planarizing process; and
i) employing a second CMP process wherein the pre-planarized thickness profile is utilized for removing the Cu diffusion barrier layer of the second portion of the sandwich layer, and wherein the second CMP process is then employed for planarizing the dielectric layer to a predetermined thickness.

2. The method of claim 1 wherein the first CMP process is selective to (1) the Cu diffusion barrier layer and (2) the dielectric layer.

3. The method of claim 1 wherein the dielectric layer and the surface of the dielectric stack have dissimilar etching characteristics.

4. A method of forming an IC structure, the method comprising:
a) forming a semiconductor substrate;
b) planarizing the semiconductor substrate to form a planarized substrate top surface;
c) depositing an etch stop layer on the planarized substrate top surface;
d) planarizing the etch stop layer to form a planarized etch stop layer;
e) depositing a dielectric layer on the planarized etch stop layer, wherein the dielectric layer comprises (1) a non-planarized top surface (2) a thinnest section and (3) a first thickness LT1 as measured at the thinnest section, that is at least substantially equal to a predetermined design thickness TD;
f) determining a pre-planarized thickness profile of the dielectric layer;
g) saving the pre-planarized thickness profile;
h) etching a trench through the dielectric layer having the non-planarized top surface, wherein the trench includes (1) sidewalls and (2) a bottom exposing the planarized top surface of the etch stop layer;
i) conformally depositing an electrically conductive Cu diffusion barrier layer on (1) the trench bottom (2) the trench sidewalls and (3) the non-planarized top surface of the dielectric layer;
j) conformally depositing a Cu seed layer on the Cu diffusion barrier layer, thereby fabricating a barrier/seed sandwich layer, wherein (1) a first portion of the sandwich layer covers the bottom and the side walls of the trench thereby forming a lined trench, and (2) a second portion of the sandwich layer covers the non-planarized top surface of the dielectric layer;
k) depositing a Cu comprising metal in the lined trench, thereby additionally forming a Cu metal comprising overburden on the second portion of the sandwich layer;
l) employing a first CMP process for removing (1) the Cu metal comprising overburden and (2) the Cu seed layer of the second portion of the sandwich layer; and
m) employing a second CMP process wherein the pre-planarizing thickness profile is utilized for removing the Cu diffusion barrier layer that is deposited on the dielectric layer and wherein the second CMP process is then employed for (1) planarizing the dielectric layer to form a planarized dielectric layer having a dielectric layer thickness LT2 that is substantially equal to the design thickness DT and (2) forming a Cu metal comprising interconnect line having a thickness IT1 that is substantially equal to the design thickness DT.

5. The method of claim 4 wherein the pre-planarized thickness profile of the dielectric layer comprises a thickness profile that is obtained prior to planarizing the dielectric layer.

6. The method of claim 4 wherein the first CMP process is selective to (1) the Cu diffusion barrier layer and (2) the dielectric layer.

7. The method of claim 4 wherein the pre-planarizing thickness profile is expressed in coordinates using computer controlled methods.

8. The method of claim 4 wherein the Cu comprising metal is selected from the group consisting of Cu and Cu alloys.

9. The method of claim 4 wherein depositing a Cu comprising metal includes depositing by means of electrochemical plating.

10. The method of claim 4 wherein depositing a Cu comprising metal includes depositing by means of electroless deposition.

11. A method of forming an IC structure, the method comprising:
a) forming a semiconductor substrate;
b) planarizing the semiconductor substrate to form a planarized substrate top surface;
c) depositing a first dielectric layer on the planarized substrate top surface;
d) planarizing the first dielectric layer to form a planarized first dielectric layer;
e) depositing a second dielectric layer on the planarized etch stop layer, wherein the second dielectric layer comprises (1) a non-planarized top surface (2) a thinnest section and (3) a first thickness LT1 as measured at the thinnest section, that is at least substantially equal to a design thickness DT, and wherein the first and second dielectric layers comprise dissimilar etching characteristics;
f) determining a pre-planarized thickness profile of the second dielectric layer;
g) saving the pre-planarized thickness profile;
h) etching a trench through the second dielectric layer having the non-planarized top surface, wherein the trench includes (1) sidewalls and (2) a bottom exposing the planarized top surface of the first dielectric layer;
i) conformally depositing an electrically conductive Cu diffusion barrier layer on (1) the trench bottom (2) the trench sidewalls and (3) the non-planarized top surface of the second dielectric layer;
j) conformally depositing a Cu seed layer on the Cu diffusion barrier layer, thereby fabricating a barrier/seed sandwich layer, wherein (1) a first portion of the sandwich layer covers the bottom and the side walls of the trench thereby forming a lined trench, and (2) a second portion of the sandwich layer covers the non-planarized top surface of the second dielectric layer;
k) depositing a Cu comprising metal in the lined trench, thereby additionally forming a Cu metal comprising overburden on the second portion of the sandwich layer;
l) employing a first CMP process, wherein the first CMP process is selective to the Cu diffusion barrier layer and the second dielectric layer, for removing (1) the Cu metal comprising overburden and (2) the Cu seed layer of the second portion of the sandwich layer; and
m) employing a second CMP process wherein the pre-planarizing thickness profile is utilized to remove the Cu diffusion barrier layer that is deposited on the second dielectric layer and wherein the second CMP process is then employed for (1) planarizing the second dielectric layer to form a planarized second dielectric layer having a second dielectric layer thickness LT2 that is substantially equal to the design thickness DT and (2) forming a Cu metal comprising interconnect line having a thickness that is substantially equal to the design thickness DT.

12. A method of forming an IC structure, the method comprising:
a) forming a semiconductor substrate;
b) planarizing the semiconductor substrate to form a planarized substrate top surface;
c) depositing a first etch stop layer on the planarized substrate top surface;
d) planarizing the first etch stop layer to form a planarized first etch stop layer surface;
e) depositing a first dielectric layer on the planarized first etch stop layer surface;
f) planarizing the first dielectric layer to form a planarized first dielectric layer surface;
g) depositing a second etch stop layer on the planarized first dielectric layer surface, wherein the first and second etch stop layers have dissimilar etching characteristics;
h) planarizing the second etch stop layer to form a planarized second etch stop layer surface;
i) depositing a second dielectric layer on the planarized second etch stop layer surface, wherein the second dielectric layer comprises (1) a non-planarized top surface (2) a thinnest section and (3) a first thickness LT1 as measured at the thinnest section, that is at least substantially equal to a predetermined design thickness DT;
j) determining a pre-planarized thickness profile of the second dielectric layer;
k) saving the pre-planarized thickness profile of the second dielectric layer;
l) etching a first via hole through (1) the second dielectric layer (2) the second etch stop layer and (3) the first dielectric layer;
m) etching a trench overlaying the first via hole, through the second dielectric layer wherein the trench includes (1) trench sidewalls and (2) a trench bottom;
n) etching a trench additionally comprising forming a second via hole extending from the trench bottom wherein the second via hole extends through the second etch stop layer and the first dielectric layer;
o) fabricating a third via hole by etching the second via hole through the first etch stop layer, wherein the third via hole comprises sidewalls and a bottom exposing the planarized substrate top surface;
p) conformally depositing an electrically conductive Cu diffusion barrier layer on (1) the third via hole bottom, (2) the third via hole sidewalls, (3) the trench bottom, (4) the trench sidewalls and (5) on the non-planarized surface of the second dielectric layer;
q) conformally depositing a Cu seed layer on the Cu diffusion barrier layer, thereby fabricating a barrier/seed sandwich layer, wherein (1) a first portion of the sandwich layer covers (i) the third via hole bottom, (ii) the third via hole sidewalls, (iii) the trench bottom and (iv) the trench sidewalls, thereby forming a lined via hole and a lined trench and (2) a second portion of the sandwich layer covers the non-planarized surface of the second dielectric layer;
r) simultaneously depositing a Cu comprising metal inside the lined trench and the lined via hole, thereby additionally forming a Cu comprising metal overburden on at the second portion of the sandwich layer;
s) employing a first CMP process for removing (1) the Cu metal comprising overburden and (2) the Cu seed layer of the second portion of the sandwich layer; and
t) employing a second CMP process wherein the pre-planarizing thickness is utilized for removing the Cu diffusion barrier layer that is deposited on the dielectric layer and wherein the second CMP process is then employed for (1) planarizing the second dielectric layer to form a planarized second dielectric layer having a layer thickness LT2 that is substantially equal to the design thickness DT and (2) forming a dual damascene structure comprising a Cu metal comprising interconnect line having a thickness that is substantially equal to the design thickness DT.

13. The method of claim 12 wherein the first CMP process is selective to the Cu diffusion barrier layer and to the second dielectric layer.

14. A method of fabricating at least a first IC structure on at least a first wafer, the method comprising:
a) selecting the first wafer wherein the first wafer comprises a first semiconductor wafer;
b) forming a first wafer dielectric stack including (1) a first wafer planarized top surface and (2) a first wafer semiconductor substrate of the first semiconductor wafer;
c) depositing a first wafer dielectric layer on the first wafer planarized top surface, wherein the first wafer dielectric layer includes (1) first wafer dielectric materials, (2) a first wafer non-planarized top surface (3) a first wafer dielectric layer thinnest section and (4) a first wafer dielectric layer thickness LT1 as measured at the thinnest section, that is at least substantially equal to a design thickness DT1;
d) determining a first wafer pre-planarized thickness profile of the first wafer dielectric layer;
e) etching a first wafer trench through the first wafer dielectric layer;
f) conformally depositing an electrically conductive first wafer Cu diffusion barrier layer inside the first wafer trench and on the first wafer non-planarized top surface of the first wafer dielectric layer;
g) conformally depositing a first wafer Cu seed layer on the first wafer Cu diffusion barrier layer, thereby fabricating a first wafer barrier/seed sandwich layer, wherein (1) a first portion of the first wafer sandwich layer is formed inside the first wafer trench, thereby forming a first wafer lined trench and (2) a second portion of the first wafer sandwich layer covers the non-planarized top surface of the first wafer dielectric layer;
h) depositing a first wafer Cu comprising metal inside the first wafer lined trench, thereby additionally forming a first wafer Cu comprising metal overburden on the second portion of the first wafer sandwich layer;
i) employing a first CMP process that is selective to the first wafer Cu diffusion barrier layer and to the first wafer dielectric layer, for removing (1) the first wafer Cu comprising metal overburden, (2) the first wafer Cu seed layer of the second portion of the first wafer sandwich layer, and wherein the first CMP process does not utilize a planarizing process; and
j) employing a second CMP process wherein the first wafer pre-planarized thickness profile is utilized for removing first wafer Cu diffusion barrier layer that is deposited on the first wafer dielectric layer, and wherein the second CMP process is then employed for (1) planarizing the first wafer dielectric layer to a thickness LT2 that is substantially equal to the design thickness DT and (2) forming a first wafer interconnect line including a thickness IT1 that is substantially equal to the design thickness DT, thereby fabricating a first IC structure on a first wafer.

15. The method of claim 14 wherein the first wafer dielectric layer and the first wafer planarized top surface have dissimilar etching characteristics.

16. The method of claim 14 wherein depositing a first wafer Cu comprising metal includes depositing by means of electrochemical plating.

17. The method of claim 14 wherein depositing a first wafer Cu comprising metal includes depositing by means of electroless deposition.

18. The method of claim 14 wherein the first wafer Cu comprising metal is selected from the group consisting of Cu and Cu alloys.

19. The method of claim 14 additionally comprising fabricating a second IC structure that is formed on a second wafer, the method comprising:
a) selecting the second wafer, wherein the second wafer comprises a second semiconductor wafer;
b) forming a second wafer dielectric stack including (1) a second wafer planarized top surface and (2) a second wafer semiconductor substrate of the second semiconductor wafer;
c) depositing a second wafer dielectric layer on the second wafer planarized top surface, wherein the second wafer dielectric layer includes (1) second wafer dielectric materials, (2) a second wafer non-planarized top surface (3) a second wafer dielectric layer thinnest section and (4) a second wafer dielectric layer thickness LT3 as measured at the thinnest section, that is at least substantially equal to the design thickness DT;
d) determining a second wafer pre-planarized thickness profile of the dielectric layer;
e) etching a second wafer trench through the second wafer dielectric layer;
f) conformally depositing an electrically conductive second wafer Cu diffusion barrier layer inside the second wafer trench and on the non-planarized top surface of the second wafer dielectric layer
g) conformally depositing a second wafer Cu seed layer on the second wafer Cu diffusion barrier layer, thereby fabricating a second wafer barrier/seed sandwich layer, wherein (1) a first portion of the second wafer sandwich layer is formed inside the second wafer trench, thereby forming a second wafer lined trench and (2) a second portion of the second wafer sandwich layer covers the non-planarized top surface of the second wafer dielectric layer;
h) depositing a second wafer Cu comprising metal inside the second wafer lined trench, thereby additionally forming a second wafer Cu comprising metal overburden on the second portion of the second wafer sandwich layer;
i) employing a third CMP process for removing (1) the second wafer Cu comprising metal overburden, (2) the second wafer Cu seed layer of the second portion of the second wafer sandwich layer, and wherein the third CMP process does not utilize a planarizing process; and
j) employing a fourth CMP process wherein the second wafer pre-planarized thickness profile is utilized for removing the second wafer Cu diffusion barrier layer that is deposited on the second wafer dielectric layer, and wherein the fourth CMP process is then employed for planarizing the second wafer dielectric layer to a thickness LT4 that is substantially equal to the design thickness DT and (2) forming a second wafer interconnect line including a thickness IT2 that is substantially equal to the design thickness DT, thereby fabricating the second IC structure.

20. The method of claim 19 wherein the first wafer dielectric materials are substantially the same as the second wafer dielectric materials.
